(19) United States
(12) Patent Application Publication
(10) Pub. No.: US 2025/0253255 A1
(43) Pub. Date: Aug. 7, 2025

(54) Unitized Finger to Bump Interposer Package

(71) Applicant: Apple Inc., Cupertino, CA (US)

(72) Inventors: Jeng-Wen P. Chen, Campbell, CA (US); Hsiu-Ping Wei, San Jose, CA (US); Fang Yu, San Jose, CA (US); Endrina S. Forti Suarez, Santa Clara, CA (US); Kwan-Yu Lai, Campbell, CA (US); Jun Zhai, Cupertino, CA (US); Young Doo Jeon, San Jose, CA (US)

(21) Appl. No.: 18/909,764

(22) Filed: Oct. 8, 2024

Related U.S. Application Data
(60) Provisional application No. 63/549,355, filed on Feb. 2, 2024.

(51) Int. Cl. H01L 23/538; H01L 23/00; H01L 23/14; H01L 23/31; H01L 23/498; H01L 25/065; H01L 25/16; H10B 80/00

(52) U.S. Cl. CPC H01L 23/5385; H01L 23/145; H01L 24/48; H01L 24/49; H01L 25/0657; H01L 23/3107; H01L 23/49811; H01L 25/167; H01L 2224/48147; H01L 2224/48157; H01L 2224/49109; H10B 80/00

(57) ABSTRACT

Electronic packages and methods of fabrication are described. In an embodiment, an electronic package includes a die stack of a plurality of vertically stacked dies, a first interposer laterally adjacent to the die stack, a first plurality of bond wires electrically connecting a first group of the plurality of vertically stacked dies to the interposer, and a molding compound layer encapsulating the die stack, the interposer, and the plurality of first plurality of bond wires.

### RELATED APPLICATIONS

This application claims the benefit of priority of U.S. Provisional Application No. 63/549,355 filed Feb. 2, 2024, which is incorporated herein by reference.

### BACKGROUND

### Field

Embodiments described herein relate to electronic packaging, and more specifically to wire bonded stacked dies.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. Furthermore, requirements for higher performance rendering, such as with video processing, requires larger and wider band memory in order to boost higher data transfer rates with the least power consumption possible.

As such, various packaging techniques have developed. For example, various 3D solutions exist in which dies are vertically stacked to integrate more functionality into the same footprint. Memory devices, for example, are often stacked into 8, 16, 32, and 64 die stacks where adjacent dies are laterally offset from one another to provide a wire bonding ledge for electrically connecting each stacked die with a package substrate with a plurality of bond wires.

### SUMMARY

Electronic packages and methods of fabrication are described. In an embodiment, an electronic package includes a die stack of a plurality of vertically stacked dies, a first interposer laterally adjacent to the die stack, a first plurality of bond wires electrically connecting a first group of the plurality of vertically stacked dies to the interposer, and a molding compound layer encapsulating the die stack, the interposer, and the plurality of first plurality of bond wires. In accordance with embodiments the interposer may include a finer via pitch than is provided in a package substrate supporting the die stack, and to which the interposer is mounted. In this manner fine wiring associated with high bond pad and via count can be offloaded to the interposer, while reducing overall electronic package size and without substantially changing the package substrate assembly line.

### BRIEF DESCRIPTION OF THE DRAWINGS

FIG. 1A is a cross-sectional side view illustration of an electronic package including a plurality of bond wires electrically connecting a die stack to bond pads of package substrate.

FIG. 1B is a schematic top-down layout view of the electronic package of FIG. 1A showing the plurality of landing pads, electrical fan out wiring and via connections within the package substrate.

FIG. 1C is a schematic cross-sectional side view illustration of an organic package substrate.

FIG. 2A is a cross-sectional side view illustration of an electronic package including a plurality of bond wires electrically connecting a die stack to bond pads of interposers mounted on a package substrate in accordance with an embodiment.

FIG. 2B is a schematic top-down layout view of the electronic package of FIG. 2A showing the plurality of landing pads and via pitch within the interposers in accordance with an embodiment.

FIG. 3A is a schematic cross-sectional side view illustration of a silicon-based interposer in accordance with an embodiment.

FIG. 3B is a schematic cross-sectional side view illustration of an organic interposer in accordance with an embodiment.

FIG. 3C is a schematic cross-sectional side view illustration of an inorganic interposer in accordance with an embodiment.

FIG. 3D is a schematic cross-sectional side view illustration of an interposer with vertical wires in accordance with an embodiment.

FIG. 4 is a schematic top view illustration of an interposer including bond pads and routing lines extending from the bond pads and over vias in accordance with an embodiment.

FIG. 5 is a schematic bottom view illustration of back side contacts on the bottom side of an interposer in accordance with an embodiment.

FIG. 6 is a schematic cross-section side view illustration of an interposer including multiple metal wiring layers in accordance with an embodiment.

FIGS. 7A-7F are schematic cross-sectional side view illustrations of a sequence of fabricating an electronic package including a plurality of bond wires electrically connecting a die stack to bond pads of interposers mounted on a package substrate in accordance with an embodiment.

FIG. 8 is a schematic cross-sectional side view illustration of an electronic package including a plurality of bond wires electrically connecting a die stack to bond pads of stacked interposers mounted on a package substrate in accordance with an embodiment.

FIG. 9 is a schematic cross-sectional side view illustration of an electronic package including a plurality of bond wires electrically connecting a die stack to bond pads of multiple interposers mounted on a package substrate in accordance with an embodiment.

FIG. 10 is a schematic cross-sectional side view illustration of an electronic package including an optical interconnect in accordance with an embodiment.

FIG. 11 is a schematic cross-sectional side view illustration of a substrate-less electronic package including a plurality of bond wires electrically connecting a die stack to bond pads of multiple interposers in accordance with an embodiment.

FIGS. 12A-12E are schematic cross-sectional side view illustrations of a sequence of fabricating a substrate-less electronic package including a plurality of bond wires electrically connecting a die stack to bond pads of multiple interposers in accordance with an embodiment.

### DETAILED DESCRIPTION

Embodiments describe wire bonded stacked dies and methods of assembly. In particular, embodiments describe wire bonded stacked memory dies in which interposers can be mounted laterally adjacent to the stacked dies, with bond wires, also referred to as “fingers,” directly connecting the stacked dies with the interposers. In this manner, the bond wire landing pad and corresponding via pitch can be defined by the interposer assembly, and be decoupled from package substrate fabrication. Furthermore, bond wire (finger) length may be reduced, mitigating challenges associated with wire sag and sway, and signal and power integrity of high speed signals.

Common package substrates include organic substrates, silicon substrates, ceramic substrates, etc. Organic substrates in particular are widely adopted to due case of manufacture and cost associated with being able to assemble in large panels. The organic dielectric materials additionally possess a suitable dielectric constant for embedding high-speed signal transmission lines. A typical organic substrate may be formed of a composite of woven fiberglass cloth and polymer (e.g. resin) and metal routing layers. The package substrate may be formed of a variety of suitable printed circuit board materials including epoxy (e.g. FR4), prepreg, polyimide, etc. The wiring layers may for formed of a copper foil with and connected with vias formed by laser etching and plating. Alternatively, both wiring layers and vias may be plated.

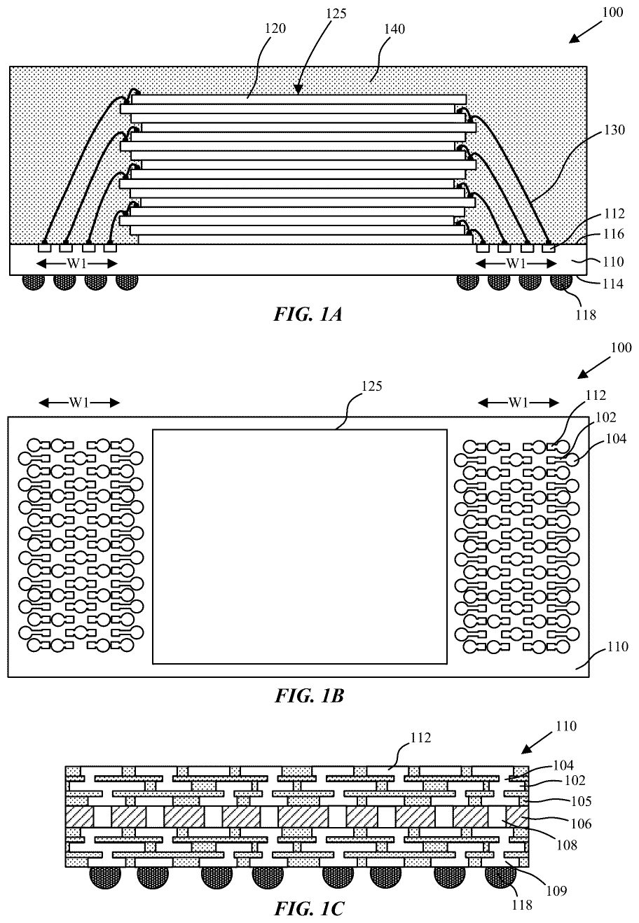

Referring now to FIG. 1A a cross-sectional side view illustration is provided of an electronic package 100 including a package substrate 110 with a front side 116 and back side 114, a die stack of plurality of dies 120 vertically stacked on the package substrate, and a plurality of bond wires 130 (or fingers) electrically connecting the die stack to bond pads 112 the package substrate 110. The plurality of vertically stacked dies 120 and bond wires 130 can then be encapsulated in a molding compound layer 140 over the front side 116 of the package substrate 110, followed by placement of solder bumps 118 on the back side 114 of the package substrate 110.

FIG. 1B is a schematic top-down layout view of the package substrate 110 showing the plurality of bond pads 112, metal wiring layer 102 routing, and via 104 connections within the package substrate 110. As shown, in both FIG. 1A and FIG. 1B, the vias 104 may require a package edge width W1 sufficient to accommodate via connections. As such, overall package 100 size and edge width W1 may be limited by technology adopted for patterning the electrical fan out wiring and vias 104 within the package substrate 110.

FIG. 1C is a schematic cross-sectional side view illustration of an organic package substrate 110. As shown, the package substrate 110 can include a plurality of dielectric layers 105 and metal wiring layers 102. Dielectric layers 105 may be formed of organic materials such as epoxy, prepreg, polyimide, etc. and may optionally be a composite of the organic materials and woven fiberglass cloth. The metal wiring layers 102 for example may optionally be a metal foil, such as copper, and may be connected with vias 104. The package substrate 110 may optionally include a core 106, such as silicon, glass, ceramic material for structural stability, and core vias 108 extending therethrough. The front side 116 of the package substrate may include bond pads 112, and the back side 114 of the package substrate may include contact pads 109 for receiving solder bumps 118. It is to be appreciated that this is an exemplary organic package substrate 110 configuration, and embodiments are not so limited.

In one aspect, it has been observed that as additional channels and banks are added to memory packages that the package size also increases with additional dies and consequential area required to accommodate additional bond wires and via pitch. More specifically, it has been observed that it can be costly at existing assembly lines to scale down bond pad 112 and via 104 pitch of standard organic package substrates, since such scaling would necessarily be applied to the entire package substrate even though it may only be necessary in areas of wire bond attach. Furthermore, inclusion of additional stacked dies and longer bond wires presents additional challenges of wire swag and sway, and degradation of signal and power integrity of high speed signals.

In accordance with embodiments, stacked die packages are described in which interposers are mounted laterally adjacent to the die stacks, with bond wires (fingers) directly connecting the stacked dies with the interposers. The interposers may have a higher via pitch/density than the package substrate. In this manner, it is not necessary to redesign the industry adopted organic package substrate 110 and assembly line, and landing pad and via pitch can be offloaded to the interposers, allowing both a reduction in overall package 100 size while maintaining existing organic package substrate 110 materials and design rules. Accordingly, the electronic package 100 size may be reduced down to wire bond capability limit. Furthermore, the interposers allow for shorter wires, which can be easier to implement in fine pitch, with less sag and sway. Signal integrity and power integrity can further be improved from shorter wires.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

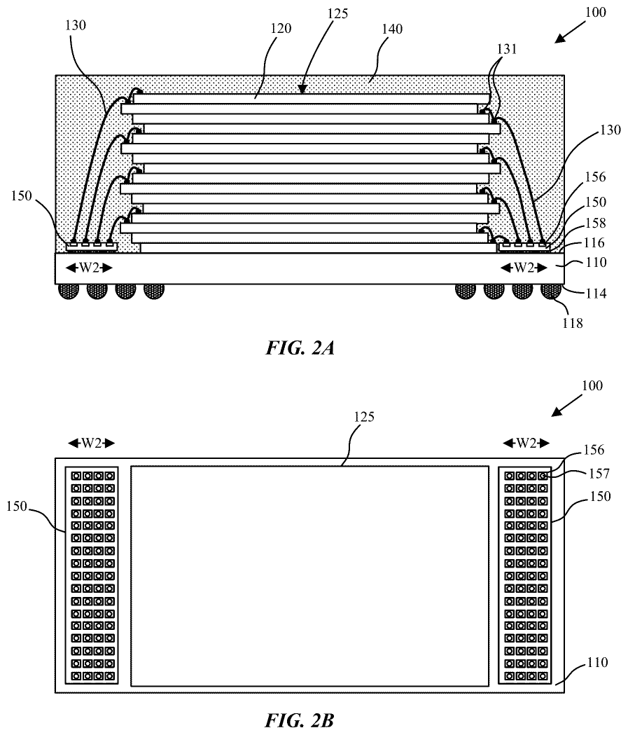

Referring now to FIGS. 2A-2B, FIG. 2A is a cross-sectional side view illustration of an electronic package 100 including a plurality of bond wires 130 electrically connecting a die stack 125 to bond pads 156 of interposers 150 mounted on a package substrate 110 in accordance with an embodiment. FIG. 2B is a schematic top-down layout view of the electronic package of FIG. 2A showing the plurality of bond pads 156 and via 157 pitch within the interposers in accordance with an embodiment. In an embodiment, the electronic package 100 includes a die stack 125 of vertically stacked dies 120, a first interposer 150 (e.g. interposer on right side of illustration) laterally adjacent to the die stack 125, and a first plurality of bond wires 130 (e.g. bond wires on right side of illustration) connecting a first group of the plurality of vertically stacked dies 120 to the first interposer 150, and a molding compound layer 140 encapsulating die stack 125, the interposer 150, and the first plurality of bond wires 130. Similarly, a second interposer 150 (e.g. interposer on left side of illustration) can be laterally adjacent to the die stack 135, and a second plurality of bond wires 130 e.g. bond wires on left side of illustration) can connect a second group of the plurality of vertically stacked dies 120 to the second interposer 150.

In the particular embodiment illustrated the die stack 125 is supported by a package substrate 110, and a corresponding interposer 150 is mounted onto the package substrate 110 on laterally opposite sides (e.g. left, right) of the die stack 125, for example, with solder bumps 158. The vertically stacked dies 120 may also be arranged in staircase arrangements so that bond ledges are exposed for connecting the bond wires 130 at ball bonds 131. In accordance with embodiments the package substrate 110 can be an organic substrate, such as that described with regard to FIG. 1C, and the interposer(s) 150 can include a finer via 157 pitch than via 104 pitch in the package substrate 110. For example, as shown in FIG. 2B vias 157 of interposers 150 can be aligned with bond pads 156, though this is not required.

In the particular embodiment illustrated in FIG. 2A, the electronic package 100 may be an 8-channel memory package, with each bond wire 130 connected corresponding to a different channel connected to the interposer 150. Moreover, the wire bonds may include single or multiple loops. In the particular embodiment illustrated each wire bond connects multiple dies 120 (two illustrated) corresponding to separate banks (e.g., 2 banks) to each bond pad 156. Embodiments may additionally support expansion to more than 4 channels or more than 2 banks.

In accordance with embodiments, the finer via 157 pitch achievable in the interposers compared to the package substrate 110 facilitates a narrower edge width W2 compared to the edge width W1, and overall reduction in size of the electronic package 100 than if the die stack 125 were wire bonded directly to the organic package substrate 110.

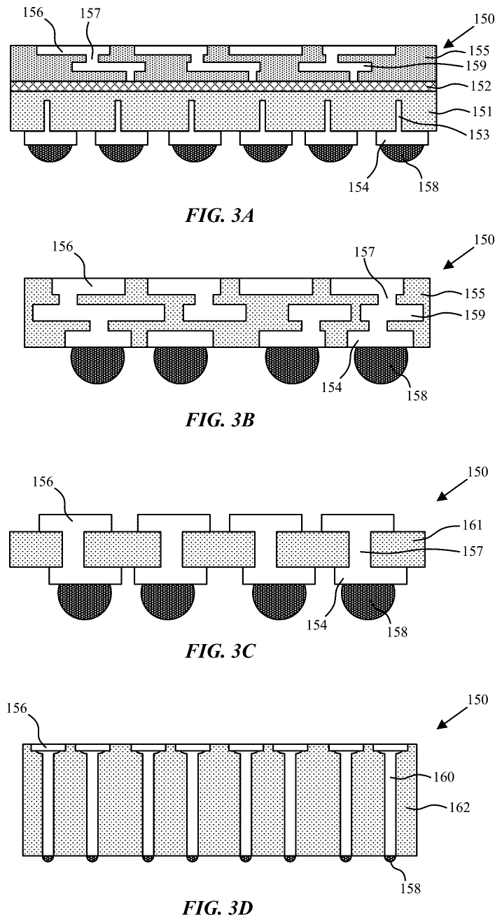

The pre-fabricated interposers 150 in accordance with embodiments may be made using various technologies including organic, silicon, glass, wires, etc. FIG. 3A is a schematic cross-sectional side view illustration of a silicon-based interposer 150 in accordance with an embodiment. As shown, the interposer 150 can include a silicon base substrate 151, and a plurality of through silicon vias 153 extending though the silicon base substrate. Such an interposer 150 may additionally include a device layer 152 in which a plurality of active and/or passive devices can be formed. In this manner, functionality from the package substrate or dies can be offloaded to the interposer 150. For example, the active device(s) may be part of a buffer, repeater, or amplifier, etc. A back end of the line (BEOL) build-up structure including one or more metal wiring layers 159, dielectric layers 155, and vias 157 can then be formed over the device layer, terminating with bond pads 156. As shown, solder bumps 158 can be placed onto back side contacts 154 for flip chip connection with the package substrate.

FIG. 3B is a schematic cross-sectional side view illustration of an organic interposer 150 in accordance with an embodiment. As shown, the organic interposer 150 can include a plurality of dielectric layers 155, metal wiring layers 159 and vias 157. The organic interposer may be fabricated similarly as the package substrate described in FIG. 1C, with a finer via 157 pitch.

FIG. 3C is a schematic cross-sectional side view illustration of an inorganic interposer 150 in accordance with an embodiment. As shown, the inorganic interposer 150 may include a ceramic base substrate 161 (e.g., glass, alumina, etc.).

FIG. 3D is a schematic cross-sectional side view illustration of an interposer 150 with vertical wires in accordance with an embodiment. For example, the vertical wires 160 can be bonded to bond pads 156, and drawn vertically, followed by encapsulation with molding compound material 162, planarization, and application of solder bumps 158.

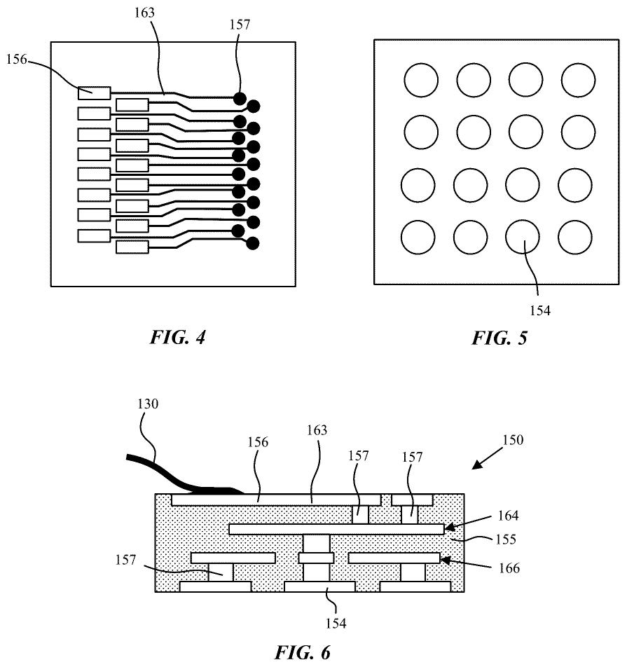

It is to be appreciated that the embodiments illustrated in FIGS. 3A-3D are exemplary and may include any number of metal wiring layers and vias 157. Referring now to FIGS. 4-5, FIG. 4 is an exemplary top view illustration of an interposer 150 including bond pads 156, and routing lines 163 extending from the bond pads 156 and over vias 157. It is to be appreciated that these are the uppermost vias 157 in the interposer. As shown, for a given interposer 150 area the bond pads 156 can be finger shaped to accommodate the bond wire 130 connection, and only so much space is available for vias 157. In accordance with embodiments, it has been observed that there can be physical constraints for available space of vias 157 if they are to be kept the same size within an organic package substrate. The interposers 150 in accordance with embodiments may be fabricated utilizing different materials and/or equipment allowing a finer via pitch, and higher via density. Referring now to FIG. 5 an exemplary bottom view illustration is provided of back side contacts 154 on the bottom side of the interposer. As shown, the back side contacts 154 can be larger, and spaced apart further than the landing pads 156 and/or uppermost vias 157. As such, the interposers 150 can be mounted on to an organic package substrate with flip chip, and solder bumps 158.

The interposers 150 in accordance with embodiments may include routing that can accommodate fine pitch via 157 escape and fan out the wiring and back side contacts 154 for compatibility with available organic package substrates. The interposers may be limited to simple fanout, or alternatively may incorporate parts of a common package substrate, such as ground planes, power planes, etc. As shown in FIGS. 4-5, the interposers may have the same number of back side contacts 154 on the back side as there are bond pads 156 on the front side. In some embodiments there may be a greater number of back side contacts 154, for example with added logic or active devices. In some embodiments there may be a fewer number of back side contacts 154 than there are bond pads 156. For example, this can be accomplished by power or ground merging, which can both reduce bump count and allow for larger vias within the interposer 150 stack-up. FIG. 6 is a schematic cross-section side view illustration of an interposer 150 including multiple metal wiring layers in accordance with embodiments. Specifically, as shown, a bond wire 130 is attached to bond pad 156. A routing line 163 extends therefrom, and over an upper most via 157. As shown, the via 157 density may be highest in the uppermost via level. The lower metal wiring layers may optionally include a ground plane 164, power plane 166, etc. In the particular embodiment illustrated, multiple vias 157 can be connected to the same ground plane 164 and back side contact 154. The lower level vias 157 may also be wider due to space savings, as well as fanout. It is to be appreciated that the illustrations of FIG. 6 is overly simplified. Furthermore, it is not required for the interposer to include ground planes, power planes, etc. as these features can also be retained in the package substrate.

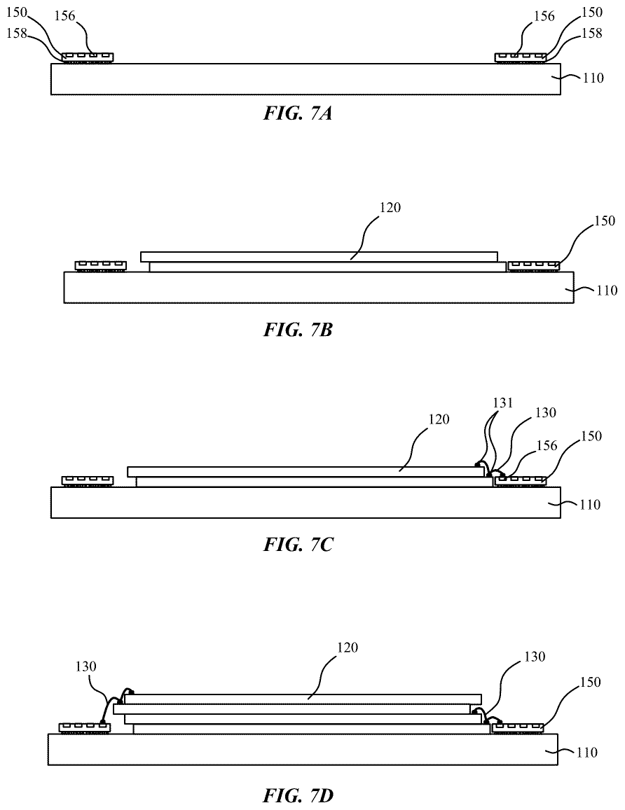

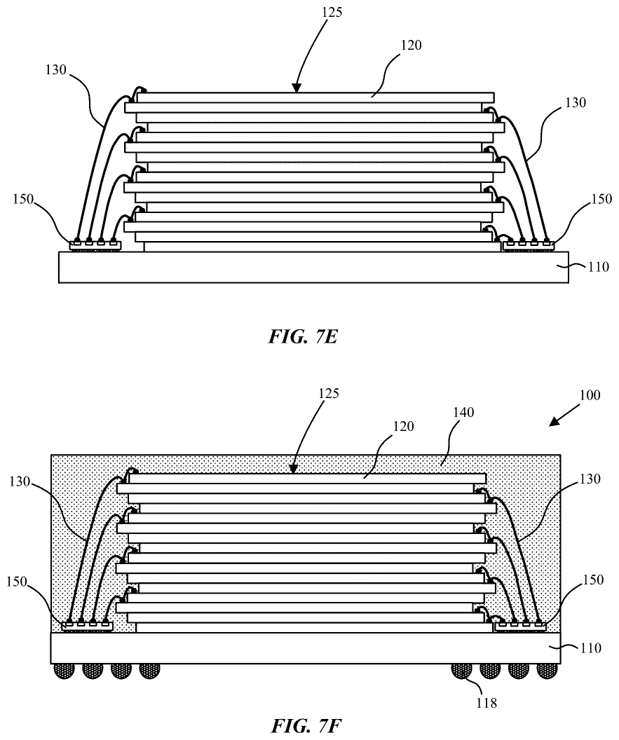

Referring now to FIGS. 7A-7F schematic cross-sectional side view illustrations are provided of a sequence of fabricating an electronic package 100 including a plurality of bond wires 130 electrically connecting a die stack 125 to bond pads 156 of interposers mounted on a package substrate 110 in accordance with an embodiment. As shown in FIG. 7A the process sequence can begin with surface mounting a plurality of interposers 150 onto a package substrate 110, for example with flip chip connection with solder bumps 158 onto bond pads 112 (see FIG. 1C) of the package substrate 110. It is to be appreciated that at this assembly stage the package substrate 110 may be part of a panel substrate, and that individual packages have not yet been singulated. A first set of dies 120 and then vertically stacked onto one another on the package substrate 110 as shown in FIG. 7B, followed by wire bonding of bond wires 130 to ledges of the dies and bond pads 156 of the interposers 150 as shown in FIG. 7C. This sequence can then be repeated for the next die set as shown in FIG. 7D, until the complete die stack 125 provided and wire bonded as shown in FIG. 7E. This may then be followed by encapsulation with molding compound layer 140, followed by application of solder bumps 118 and singulation of multiple electronic packages 100 as shown in FIG. 7F.

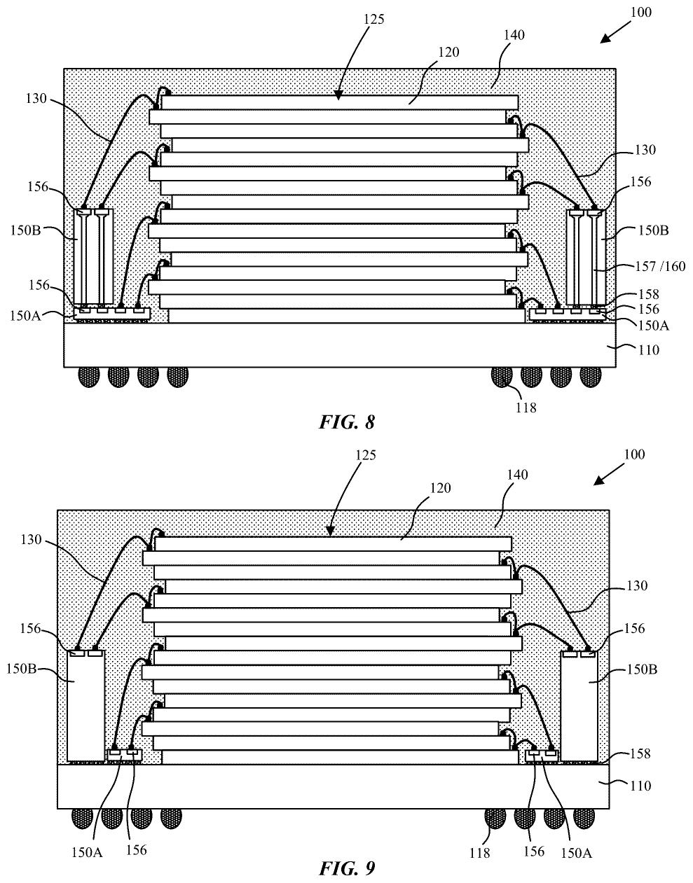

The electronic packages in accordance with embodiments can include a variety of interposer 150 arrangements. FIG. 8 is a schematic cross-sectional side view illustration of an electronic package 100 including a plurality of bond wires 130 electrically connecting a die stack 125 to bond pads 156 of stacked interposers 150 mounted on a package substrate 110 in accordance with an embodiment. In the illustrated embodiment, the electronic package includes a first interposer 150A, a second interposer 150B mounted on top of the first interposer 150B. First and second pluralities of bond wires 130 are electrically connected to corresponding groups of dies 120 and the corresponding first and second interposers. As shown, the second interposers 150B can be mounted onto bond pads 156 of the first interposers with solder bumps 158. The second interposers 150B may optionally be taller than the first interposers 150A. In the illustrated arrangements, the bond wire 130 lengths to the second interposers 150B is significantly reduced.

FIG. 9 is a schematic cross-sectional side view illustration of an electronic package 100 including a plurality of bond wires 130 electrically connecting a die stack 125 to bond pads of multiple interposers mounted on a package substrate in accordance with an embodiment. FIG. 9 is substantially similar to the configuration of FIG. 8, with one difference being that the first interposer 150A and second interposer 150B are mounted side-by-side on the package substrate 110. Similar to the description of FIG. 8, the second (taller) interposer 150B may be wire bonded to the top stacked dies 120.

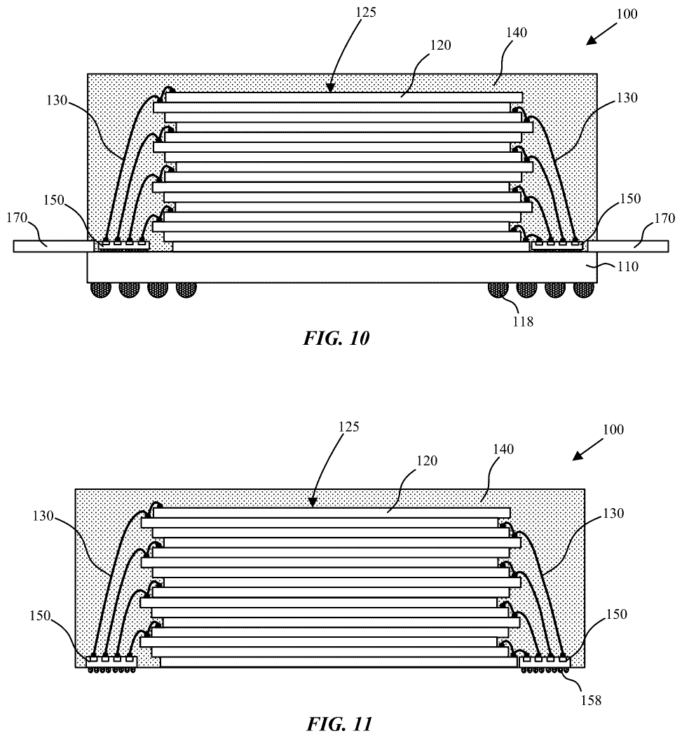

The interposers in accordance with embodiments may have additional functionality. Referring now to FIG. 10 a schematic cross-sectional side view illustration of an electronic package 100 including an optical interconnect 170 in accordance with an embodiment. As shown, the optical interconnect 170 (such as optical fiber, etc.) can be mounted side-by-side with the interposer 150. In such an instance, the interposer can additionally include an optical emitter or optical detector that aligned with the optical fiber for optical communication to/from the electronic package 100. Furthermore, the interposer may have an electrical-to-optical converter coupled with an optical emitter, and/or an optical-to-electrical converter coupled with an optical detector.

Up until this point embodiments have been described in which the die stack and interposers are supported by a package substrate. FIG. 11 is a schematic cross-sectional side view illustration of a substrate-less electronic package 100 including a plurality of bond wires 130 electrically connecting a die stack 125 to bond pads of multiple interposers 150 in accordance with an embodiment. As shown, a plurality of solder bumps 158 can be applied directly to the interposer 150 back side contacts 154 (see FIGS. 3A-3D). Thus, the electrical connection can be made directly to the interposers 150 on the bottom side of the electronic package 100. Such a package arrangement can be fabricated utilizing a similar process.

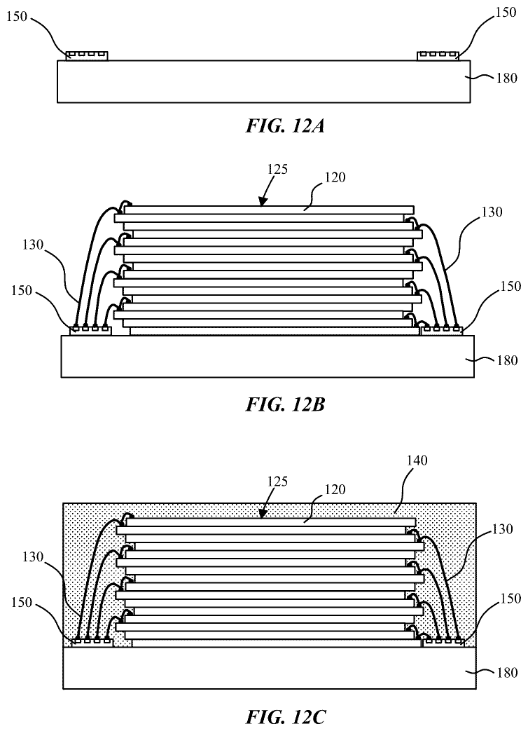

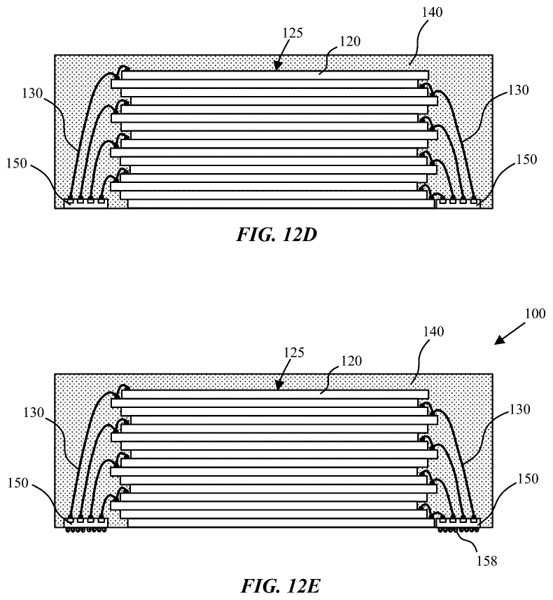

FIGS. 12A-12E are schematic cross-sectional side view illustrations of a sequence of fabricating a substrate-less electronic package 100 including a plurality of bond wires 130 electrically connecting a die stack 125 to bond pads of multiple interposers 150 in accordance with an embodiment. It is to be appreciated that while the processing sequence is shown with regard to the electronic package of FIG. 11, that such a processing sequence can be used to fabricate a substrate-less package similar to any of the packages illustrated and described herein. Referring now to FIG. 12A, a plurality of interposers 150 can be mounted onto a carrier substrate 180, such as glass, metal, silicon, etc. which may be coated with an adhesive tape. This may be followed by mounting of the die stack 125 and wire bonding as shown in FIG. 12B, followed by encapsulation with molding compound layer 140 as shown in FIG. 12C. At this point the carrier substrate 180 and adhesive tape can be removed to expose the back side contacts 154 (see FIGS. 3A-3D) of the interposers as shown in FIG. 12D, followed by application of solder bumps 158 and singulation of multiple substrate-less electronic packages 100 as shown in FIG. 12E.

In utilizing the various aspects of the embodiments, it would become apparent to one skilled in the art that combinations or variations of the above embodiments are possible for forming a unitized finger to bump interposer package. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic package comprising:
a die stack of a plurality of vertically stacked dies;
a first interposer laterally adjacent to the die stack;
a first plurality of bond wires electrically connecting a first group of the plurality of vertically stacked dies to the interposer; and
a molding compound layer encapsulating the die stack, the interposer, and the plurality of first plurality of bond wires.

2. The electronic package of claim 1, wherein the die stack is supported by a package substrate, and the first interposer is mounted on the package substrate with a plurality of solder bumps.

3. The electronic package of claim 2, wherein the package substrate is an organic substrate.

4. The electronic package of claim 3, wherein the interposer includes a finer via pitch than the organic substrate.

5. The electronic package of claim 4, wherein the interposer includes a silicon base substrate.

6. The electronic package of claim 5, further comprising a plurality of through silicon vias extending through the silicon base substrate.

7. The electronic package of claim 5, wherein the interposer comprises an active device.

8. The electronic package of claim 7, wherein the active device is part of a buffer, repeater, or amplifier.

9. The electronic package of claim 4, wherein the interposer comprises a plurality of vertical wires.

10. The electronic package of claim 4, wherein the interposer comprises a ceramic base substrate.

11. The electronic package of claim 1, further comprising:
a second interposer mounted on top of the first interposer; and
a second plurality of bond wires electrically connecting a second group of the plurality of vertically stacked dies to the second interposer;
wherein the molding compound layer encapsulates the second interposer and the second plurality of bond wires.

12. The electronic package of claim 11, wherein the second interposer is taller than the first interposer.

13. The electronic package of claim 1, further comprising:
a second interposer laterally adjacent to the first interposer; and
a second plurality of bond wires electrically connecting a second group of the plurality of vertically stacked dies to the second interposer;
wherein the molding compound layer encapsulates the second interposer and the second plurality of bond wires.

14. The electronic package of claim 13, wherein the second interposer is taller than the first interposer.

15. The electronic package of claim 1, further comprising an optical interconnect adjacent to the first interposer.

16. The electronic package of claim 15, wherein the optical interconnect comprises an optical fiber.

17. The electronic package of claim 16, wherein the first interposer comprises an optical emitter or optical detector.

18. The electronic package of claim 1, further comprising a plurality of solder bumps on a bottom side of the electronic package, wherein the plurality of solder bumps is in direct contact with the first interposer.

19. The electronic package of claim 1, wherein the dies are memory dies.

20. The electronic package of claim 19, wherein the electronic package comprises at least 4 channels.

21. The electronic package of claim 1, wherein a pair of the first plurality of bond wires are bonded to a first pair of bond pads of the interposer, and the first pair of bond pads is electrically connected to a same back side contact of the interposer.
